(19) United States
(12) Patent Application Publication
(10) Pub. No.: US 2004/0056343 A1
(43) Pub. Date: Mar. 25, 2004

(54) Getters

(76) Inventor: John Leonello Casci, cleveland (GB)

Correspondence Address: RATNERPRESTIA, P O BOX 980, VALLEY FORGE, PA, 19482-0980, US

(21) Appl. No.: 10/432,426

(22) PCT Filed: Oct. 24, 2001
(86) PCT No.: PCT/GB01/04695

(30) Foreign Application Priority Data
Nov. 22, 2000 (GB) GB0028395.2

(51) Int. Cl. H01L 23/20; H01S 5/00

(52) U.S. Cl. 257/682; 372/43

(57) ABSTRACT

A getter for use in a sealed enclosure in the form of a porous body formed from particles of a FAU zeolite having a silica to alumina molar ratio below 10 and particles of a high silica to alumina molar ratio zeolite, having a silica to alumina molar ratio of at least 20, bound together with an inorganic binder. The high silica to alumina zeolite is preferably de-aluminated zeolite FAU or *BEA.

This invention relates to getters and in particular to getters for electrical and electronic applications. Getters are often used within a sealed enclosure forming part of, or a housing for, the electrical or electronic device, to remove unwanted materials from the atmosphere within the enclosure.

It has been proposed in U.S. Pat. No. 5,696,785 to provide, as a getter for a high power laser enclosure, a composition consisting of two types of adsorbent bound with an inorganic binder. The first type of adsorbent, therein termed a “W” component, was a material having a pore or channel size suitable for immobilising water, selected from a list of certain natural and synthetic zeolitic materials, including zeolites 3A, 4A and 5A. Generally the listed materials have a pore size below about 0.6 nm and having a silica to alumina molar ratio below about 6. The other adsorbent, therein termed a “O” component, was a material having a pore size suitable for immobilising the larger organic molecules and was selected from a list of materials, some of which were natural and synthetic zeolitic materials having pore sizes at or above about 0.6 nm. The listed zeolitic materials, which included, inter alia, FAU zeolites, e.g. zeolite X and zeolite Y, had a wide range of silica to alumina ratios ranging from the high alumina materials, wherein the silica to alumina ratio is about 2, to the low alumina materials, where, in some cases, any alumina is present essentially only as an impurity and so the zeolitic material is essentially alumina free.

We have devised improved getter materials where both adsorbent components are of the larger pore size characteristic of the aforementioned “O” components. We have found compositions that have an increased adsorption capacity compared to the compositions of U.S. Pat. No. 5,696,785.

Accordingly the present invention provides a getter for use in a sealed enclosure, in the form of a porous body formed from particles of a FAU zeolite having a silica to alumina molar ratio below 10 and particles of a high silica to alumina molar ratio zeolite, having a silica to alumina molar ratio of at least 20, bound together with an inorganic binder.

The FAU zeolites, X and Y, have the Faujisite structure. Zeolite X has a low silica to alumina (SiO₂/Al₂ O₃) molar ratio, namely about 2, and is hydrophilic and is a good adsorbent for water. Similarly those forms of zeolite Y having a silica to alumina molar ratio below about 10 are hydrophilic and are good water absorbents.

The zeolites having a high silica to alumina molar ratio are hydrophobic. Examples of suitable high silica zeolites include those zeolites *BEA, ERI, EUO, FAU, FER, MAZ, MEl, MEL, MFI, MFS, MTT, MTW, NES, OFF, TON, CLO, MCM-22, NU-86 and NU-88 having silica to alumina molar ratios of at least 20, whether made by direct synthesis or by post-synthesis modification. [The 3-letter designation codes are those set up by an IUPAC Commission on Zeolite Nomenclature. Full listings are available in the “Atlas of Zeolite Structure Types” published by Elsevier]. Thus there may be used as zeolites having a high silica to alumina ratio, zeolites having a lower silica to alumina ratio that have had their silica to alumina molar ratio increased post synthesis by de-alumination and/or by silylation. Thus zeolite Y, having a silica to alumina molar ratio of about 4-5, may have its silica to alumina molar ratio increased to well above 20 by de-alumination, for example by acid extraction and/or steaming. De-aluminated zeolite Y having silica to alumina molar ratios up to about 120 are known and there are reports of materials with even higher silica to alumina ratios. All such materials are encompassed in this description. Zeolite beta (*BEA) is commonly synthesised with silica to alumina molar ratios above about 16, but much higher silica to alumina ratios can be obtained by de-alumination.

The preferred high silica to alumina ratio zeolites are de-aluminated FAU and *BEA.

The composition may contain the low silica to alumina ratio FAU zeolite and the high silica to alumina molar ratio zeolite in any suitable proportions. Preferably there are 0.25 to 4 parts, particularly 0.5 to 2 parts, by weight of the low silica to alumina ratio FAU zeolite per part by weight of the high silica to alumina molar ratio zeolite.

The binder Is any suitable inorganic binder material. Preferred binders are non-porous silicas such as colloidal silica or fumed silica. The composition preferably contains 5 to 25% by weight of the binder.

The getter may be made by tabletting a powder mixture of the zeolite components and binder, followed by calcination, at e.g. 300° C. to 60020 C. to effect some inter particle bonding to give adequate physical strength. Pelleting aids such a graphite or metal stearates may be included in the powder mixture, but since at the preferred calcination temperatures graphite may only be partially removed, stearates, especially magnesium stearate, are preferred pelleting aids. Alternatively the getter may be made by other shaping techniques such as roll compacting or paste extrusion followed as necessary by calcination to remove any extrusion aids etc.

To assist with the extrusion or granulation process, or indeed to assist in the preparation of a paste which is subsequently dried and milled before tabletting, certain organic components may be added. These organic components can be readily removed during any calcination stage (as described above) leaving no residual organic species. For the tabletting process convenient organic additives include polyvinyl alcohol or cellulose materials such as microcrystalline cellulose.

Tabletting (or compaction) is the preferred method of preparing the final form. This is because it provides a higher density formed body than other methods of forming such as extrusion or granulation and can give products having a close dimensional tolerance. The higher density allows a higher mass loading of getter into a housing of a certain volume or alternately allows the same mass of getter to be enclosed in a smaller volume: this is an important consideration for electronic and opto-electronic devices where overall physical dimensions are an important feature. The close dimensional tolerance allows preparation of getters which may fit tightly into a c rtain housing or retaining unit and, most importantly, allows very thin getters (for example about 1 mm thickness) to be prepared.

Accordingly a preferred method of making tablets suitable for use as a getter comprises forming a homogeneous paste from a mixture of particles of a FAU zeolite having a silica to alumina molar ratio below 10, particles of a zeolite having a silica to alumina molar ratio of at least 20, an inorganic binder, water and an organic processing aid, drying the paste, milling the dried paste, compacting the milled composition into a tablets, and calcining the tablets to remove the organic processing aid.

Getters in accordance with the present invention may be employed for a variety of applications including certain electrical, electronic and/or opto-electronic devices e.g. high power laser enclosures.

The getters are useful for the removal of water vapour and/or hydrocarbons and/or other organic compounds such as solvents. The water can have the effect of reducing the overall life of the device by causing corrosion or electrical short-circuits, while the organic compounds, e.g. hydrocarbons, can either attenuate the signal in an opto-electronic device or give rise to carbonaceous residues, e.g. as a result of charring by a laser, which affect the lifetime or efficacy of the device.

The invention is illustrated by the following examples in which all parts and percentages are expressed by weight.

### EXAMPLE 1

An aluminium-rich FAU zeolite powder having a silica to alumina molar ratio of 5.1 and an aluminium-deficient FAU zeolite powder having a silica to alumina molar ratio of 68 were allowed to pre-equilibrate under normal laboratory humidity in beds of about 1 cm deep in shallow trays for at least 24 hours. This was to allow the zeolitic materials to saturate with water vapour. The moisture content was determined by drying a sample at 300° C. for 6 hours. This moisture content was allowed for when calculating the quantities of the zeolites used.

1383 parts of the aluminium-rich FAU, which contained 27.7% moisture, and 1000 parts of the aluminium-deficient FAU, which contained less than 1% moisture, were mixed in a powder mixer for 15 minutes. The mixed powders were combined with 1667 parts a colloidal silica sol containing 30% silica and 1425 parts of de-mineralised water in a Hobart mixer and mixing continued for 45 minutes. Periodically, about every 15 minutes, the walls of the mixer were scraped down by hand to ensure that all the material is mixed into the bulk. 573 parts of a solution containing 1.5% of polyvinylalcohol were added the resulting paste and mixing continued for a further 45 minutes with periodic hand mixing every 15 minutes. The resulting homogeneous paste was poured onto trays to give layers of depth about 2 cm and allowed to air dry for at least 24 hours, then oven dried at 50° C. for a further 24 hours.

The resulting dried cake was milled, sieved to a size fraction of 150-500 μm and then tabletted on a Fette P1200 tabletting machine using 5.4 mm diameter tooling. The resulting tablets were calcined in air at 550° C. for 6 hours to remove the organic binder.

The resultant getter tablets consisted of about 40% of the aluminium-rich FAU zeolite, 40% of the aluminium deficient (de-aluminated) FAU zeolite and 20% of amorphous silica.

### EXAMPLE 2

Example 1 was repeated using microcrystalline cellulose in place of the polyvinylalcohol solution to assist processing. Thus 125 parts of a microcrystalline cellulose (Avicel NT020 supplied by the FMC Corporation) was included in the dry powder mixing of the aluminium-rich FAU zeolite and the aluminium-deficient FAU zeolite and 1585 parts of de-mineralised water were used in place of the 1425 parts used in Example 1. After mixing the powders with the demineralised water and the silica sol for 45 minutes in a Hobart mixer a homogeneous paste was obtained. The step of addition of the polyvinylalcohol solution and subsequent continued Hobart mixing was omitted. Thus the paste was poured into the trays after a total Hobart mixing time of 45 minutes. In order to ensure complete removal of the microcrystalline cellulose, the tablets were calcined a second time in air for 6 hours at 550° C.

### EXAMPLE 3

Example 1 was repeated but using 2075 parts of the aluminium rich FAU zeolite and 500 parts of the aluminium deficient FAU zeolite. The amount of demineralised water used was 1464 parts. The polyvinyl alcohol solution was added after Hobart mixing for 15 minutes and the total Hobart mixing time was 60 minutes.

The resultant getter tablets consisted of about 60% of the aluminium-rich FAU zeolite, 20% of the aluminium deficient (de-aluminated) FAU zeolite and 20% of amorphous silica.

### EXAMPLE 4

Example 2 was repeated but using 1408 parts of the aluminium rich FAU zeolite which had a moisture content of 29%, and 1250 parts of a de-aluminated *BEA zeolite having a silica to alumina molar ratio of 270 and a moisture content of 20% in place of the alumina-deficient FAU zeolite. The amount of demineralised water used was 1450 parts and the Hobart mixing was effected for 30 minutes.

The resultant getter tablets consisted of about 40% of the aluminium-rich FAU zeolite, 40% of the aluminium deficient (de-aluminated) *BEA zeolite and 20% of amorphous silica.

### EXAMPLE 5

Example 4 was repeated but using 2112 parts of the aluminium rich FAU and 625 parts of the de-aluminated *BEA zeolite. The amount of demineralised water used was 1463 parts and the Hobart mixing was effected for 30 minutes with hand mixing every 10 minutes.

The resultant getter tablets consisted of about 60% of the aluminium-rich FAU zeolite, 20% of the aluminium deficient (de-aluminated) *BEA zeolite and 20% of amorphous silica.

### EXAMPLE 6

The tabletting feed from Example 5 was tabletted using the Fette P1200 machine using different diameter tooling. The tablets were calcined in air at 550° C. for 6 hours, twice, to remove the microcrystalline cellulose.

The dimensions, weight and crush strength (mean and standard deviation, SD) of a representative sample of 10 tablets from each of Examples 3 to 6 were determined and are shown in Table 1.

TABLE 1

| | diameter | | Thickness | | | | crush | |
|---|---|---|---|---|---|---|---|---|
| | (mm) | | (mm) | | weight (g) | | strength (N) | |
| Example | mean | SD | Mean | SD | mean | SD | mean | SD |
| 3 | | | 1.54 | 0.021 | 0.0409 | 0.00137 | 73.0 | 9.7 |
| 4 | | | 1.24 | 0.009 | 0.0371 | 0.00057 | 47.8 | 10.3 |
| 5 | | | 1.21 | 0.03 | 0.0361 | 0.0012 | 51.5 | 4.3 |
| 6 | 2.77 | 0.01 | 1.47 | 0.014 | 0.0113 | n/a | | |
| | 20.2 | 0.05 | 8.10 | 0.056 | 2.378 | 0.022 | | |

It is seen from the above table that the tablets had a close size and weight tolerance.

### EXAMPLE 7

The getter tablets from Examples 1 and 3 were activated (out-gassed) by heating in air at 300° C. for 4 hours. The tablets were then cooled in a dessicator over P₂O₅. The tablets were then weighed, exposed at ambient temperature to an atmosphere at or above a relative humidity of 40% for 8 hours and then re-weighed. The water uptake was thus determined. The results (averaged over 3 groups of 5 tablets each) are shown in Table 2.

TABLE 2

| Example | Al rich/Al deficient weight ratio | Water uptake (%) |
|---|---|---|
| 1 | 2 | 11.1 |
| 3 | 3 | 15.1 |

It can be seen that as the proportion of the Al-rich FAU (employed to remove water) is increased, the water uptake capacity also increases. It is evident that one can vary the amount of the two components in a continuous manner to tailor the getter to the required balance between water and organic removal. Thus the quantity of the water absorbing or hydrocarbon/tsolvent absorbing components can be altered to suit particular requirements.

It will also be evident that materials such as aluminium-deficient FAU and/or *BEA, which have large pore openings, are capable of absorbing the typical hydrocarbons and organic contaminants of concern: namely hydrocarbons, solvents and the like.

1. A getter for use in a sealed enclosure in the form of a porous body formed from particles of a FAU zeolite having a silica to alumina molar ratio below 10 and particles of a high silica to alumina molar ratio zeolite having a silica to alumina molar ratio of at least 20, bound together with an inorganic binder.

2. A getter according to claim 1 wherein the high silica to alumina molar ratio zeolite is selected from zeolites *BEA, ERI, EUO, FAU, FER, MAZ, MEI, MEL, MFI, MFS, MTT, MTW, NES, OFF, TON, CLO, MCM-22, NU-86 and NU-88 having a silica to alumina molar ratio of at least 20.

3. A getter according to claim 1 wherein the high silica to alumina molar ratio zeolite is de-aluminated zeolite FAU or *BEA.

4. A getter according to any one of claims 1 to 3 containing 0.25 to 4 parts by weight of the FAU zeolite having a silica to alumina molar ratio below 10 per part by weight of the high silica to alumina molar ratio zeolite.

5. A getter according to any one of claims 1 to 4 wherein the FAU zeolite is zeolite X.

6. A getter according to any one of claims 1 to 5 wherein the binder is colloidal silica or fumed silica.

7. A getter according to any one of claims 1 to 6 containing 5 to 25% by weight of the binder.

8. A method of making tablets suitable for use as a getter comprising forming a homogeneous paste from a mixture of particles of a FAU zeolite having a silica to alumina molar ratio below 10, particles of a zeolite having a silica to alumina molar ratio of at least 20, an inorganic binder, water and an organic processing aid, drying the paste, milling the dried paste, compacting the milled composition into a tablets, and calcining the tablets to remove the organic processing aid.

9. A method according to claim 8 wherein the organic processing aid is microcrystalline cellulose and or polyvinyl alcohol.

10. Electrical, electronic or opto-electronic apparatus including a sealed enclosure containing a getter according to any one of claims 1 to 7.
